(19) United States
(12) Patent Application Publication
(10) Pub. No.: US 2025/0274117 A1
(43) Pub. Date: Aug. 28, 2025

(54) SEMICONDUCTOR DEVICE AND METHOD OF CONTROLLING SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Teruyuki OHASHI, Kawasaki Kanagawa (JP); Tatsunori SAKANO, Shinagawa Tokyo (JP); Hiroshi KONO, Himeji Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/049,707

(22) Filed: Feb. 10, 2025

(30) Foreign Application Priority Data
Feb. 28, 2024 (JP) 2024-029014

(51) Int. Cl. H03K 17/16; H03K 17/0812; H10D 62/832; H10D 84/00

(52) U.S. Cl. CPC H03K 17/162; H03K 17/08122; H10D 62/8325; H10D 84/146

(57) ABSTRACT

A semiconductor device according to an embodiment includes: a transistor, the transistor including a first electrode, a second electrode, semiconductor regions provided between the first electrode and the second electrode, and a gate electrode; a detector detecting a voltage of the first electrode or a current flowing from the first electrode to the second electrode in a state where the voltage of the first electrode is a positive voltage higher than a voltage of the second electrode; a comparison circuit comparing a measurement value measured by the detector with a first threshold; and a gate driver circuit applying a first positive voltage higher than a threshold voltage of the transistor to the gate electrode, and applying a first negative voltage to the gate electrode when the measurement value exceeds the first threshold as a result of comparison in the comparison circuit.

### CROSS-REFERENCE TO RELATED APPLICATION

This application is based upon and claims the benefit of priority from Japanese Patent Application No. 2024-029014, filed on Feb. 28, 2024, the entire contents of which are incorporated herein by reference.

### FIELD

Embodiments described herein relate generally to a semiconductor device and a method of controlling a semiconductor device.

### BACKGROUND

There is silicon carbide as an example of a material for next-generation semiconductor devices. As compared with silicon, the silicon carbide has superior physical properties such as a threefold band gap, approximately tenfold breakdown field strength, and approximately threefold thermal conductivity. By using the above characteristics, it is possible to realize a metal oxide semiconductor field effect transistor (MOSFET) capable of operating at high temperature with high breakdown voltage and low loss, for example.

A vertical MOSFET using silicon carbide includes a pn junction diode as a built-in diode. For example, the MOSFET is used as a switching element connected to an inductive load. In this case, even when the MOSFET is in an off state, a reflux current can be caused to flow by using the built-in diode.

A large surge current may flow through the MOSFET instantaneously beyond a steady state. When the large surge current flows, the MOSFET generates heat and breaks down. A maximum allowable peak current value (I_{FSM}), which is a surge current allowed in the MOSFET, is referred to as a surge current resistance. In the MOSFET, it is desired to improve the surge current resistance.

### BRIEF DESCRIPTION OF THE DRAWINGS

FIG. 1 is a block diagram of a semiconductor device according to a first embodiment;

FIG. 2 is a schematic cross-sectional view of a transistor according to the first embodiment;

FIG. 3 is a diagram illustrating a specific example of the semiconductor device according to the first embodiment;

FIG. 4 is an explanatory diagram of a method of controlling the semiconductor device according to the first embodiment;

FIGS. 5A, 5B, 5C, 5D, 5E, and 5F are explanatory diagrams of the method of controlling the semiconductor device according to the first embodiment;

FIG. 6 is a block diagram of a semiconductor device according to a comparative example;

FIG. 7 is an explanatory diagram of a method of controlling the semiconductor device according to the comparative example;

FIGS. 8A, 8B, 8C, and 8D are explanatory diagrams of the method of controlling the semiconductor device according to the comparative example;

FIG. 9 is an explanatory diagram of functions and effects of the semiconductor device according to the first embodiment;

FIG. 10 is an explanatory diagram of functions and effects of the semiconductor device according to the first embodiment;

FIG. 11 is an explanatory diagram of functions and effects of the semiconductor device according to the first embodiment;

FIGS. 12A and 12B are explanatory diagrams of functions and effects of the semiconductor device according to the first embodiment;

FIG. 13 is an explanatory diagram of functions and effects of the semiconductor device according to the first embodiment;

FIG. 14 is a block diagram of a semiconductor device according to a modification of the first embodiment;

FIG. 15 is an explanatory diagram of a method of controlling the semiconductor device according to the modification of the first embodiment;

FIG. 16 is a block diagram of a semiconductor device according to a second embodiment;

FIG. 17 is a schematic cross-sectional view of a transistor according to the second embodiment; and

FIG. 18 is a block diagram of a semiconductor device according to a modification of the second embodiment.

### DETAILED DESCRIPTION

A semiconductor device according to an embodiment includes: a transistor, the transistor including a first electrode, a second electrode, an n-type first semiconductor region provided between the first electrode and the second electrode and electrically connected to the second electrode, a p-type second semiconductor region provided between the first semiconductor region and the first electrode and electrically connected to the first electrode, an n-type third semiconductor region provided between the second semiconductor region and the first electrode and electrically connected to the first electrode, and a gate electrode facing the second semiconductor region; a detector configured to detect a voltage of the first electrode or a current flowing from the first electrode to the second electrode in a state where the voltage of the first electrode is a positive voltage higher than a voltage of the second electrode; a comparison circuit configured to compare a measurement value measured by the detector with a first threshold in the state; and a gate driver circuit configured to apply a first positive voltage higher than a threshold voltage of the transistor to the gate electrode in the state, and apply a first negative voltage to the gate electrode when the measurement value exceeds the first threshold as a result of comparison in the comparison circuit.

Hereinafter, embodiments of the present disclosure will be described with reference to the drawings. In the following description, the same or similar members are denoted by the same reference numerals and the description of the members described once may be appropriately omitted.

In addition, in the following description, notations n⁺, n, n⁻, p⁺, p, and p⁻ represent the relative magnitudes of impurity concentrations in respective conductivity types. That is, an n-type impurity concentration of n⁺ is relatively higher than an n-type impurity concentration of n and an n-type impurity concentration of n⁻ is relatively lower than the n-type impurity concentration of n. In addition, a p-type impurity concentration of p⁺ is relatively higher than a p-type impurity concentration of p and a p-type impurity concentration of p⁻ is relatively lower than the p-type impurity concentration of p. The n⁺ type and the n⁻ type may be simply described as the n types and the p⁺ type and the p⁻ type may be simply described as the p types.

The impurity concentration can be measured by secondary ion mass spectrometry (SIMS), for example. In addition, the relative magnitude of the impurity concentration can be determined from the magnitude of a carrier concentration obtained by scanning capacitance microscopy (SCM), for example. In addition, a distance such as a depth and a thickness of an impurity region can be obtained by the SIMS, for example. In addition, the distance such as the depth, the thickness, the width, and the interval of the impurity region can be obtained from a combined image of an SCM image and an atomic force microscope (AFM) image, for example.

In the present specification, it is assumed that an impurity concentration of a semiconductor region means a maximum impurity concentration of the semiconductor region unless otherwise stated.

### First Embodiment

A semiconductor device according to a first embodiment includes: a transistor, the transistor including a first electrode, a second electrode, an n-type first semiconductor region provided between the first electrode and the second electrode and electrically connected to the second electrode, a p-type second semiconductor region provided between the first semiconductor region and the first electrode and electrically connected to the first electrode, an n-type third semiconductor region provided between the second semiconductor region and the first electrode and electrically connected to the first electrode, and a gate electrode facing the second semiconductor region; a detector configured to detect a current flowing from the first electrode to the second electrode in a state where a voltage of the first electrode is a positive voltage higher than a voltage of the second electrode; a comparison circuit configured to compare a measurement value measured by the detector with a first threshold in the state; and a gate driver circuit configured to apply a first positive voltage higher than a threshold voltage of the transistor to the gate electrode in the state, and apply a first negative voltage to the gate electrode when the measurement value exceeds the first threshold as a result of comparison in the comparison circuit.

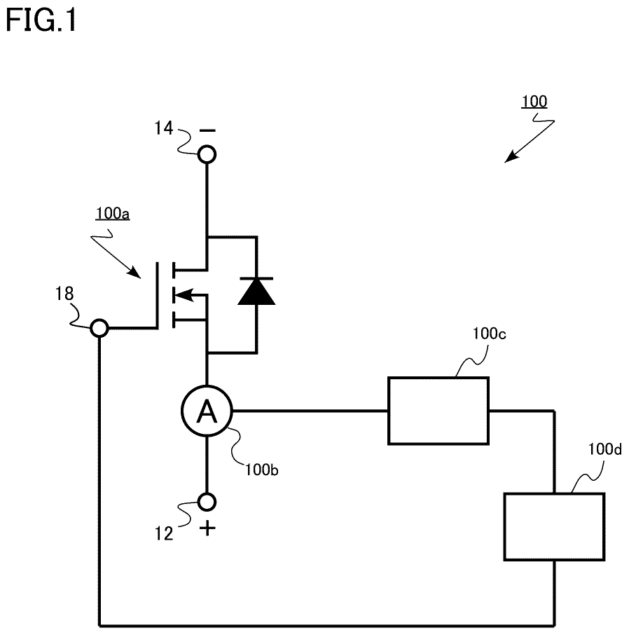

FIG. 1 is a block diagram of the semiconductor device according to the first embodiment. The semiconductor device according to the first embodiment is a semiconductor module 100 including a transistor 100a using silicon carbide.

The semiconductor module 100 includes a transistor 100a, an ammeter 100b, a comparison circuit 100c, and a gate driver circuit 100d.

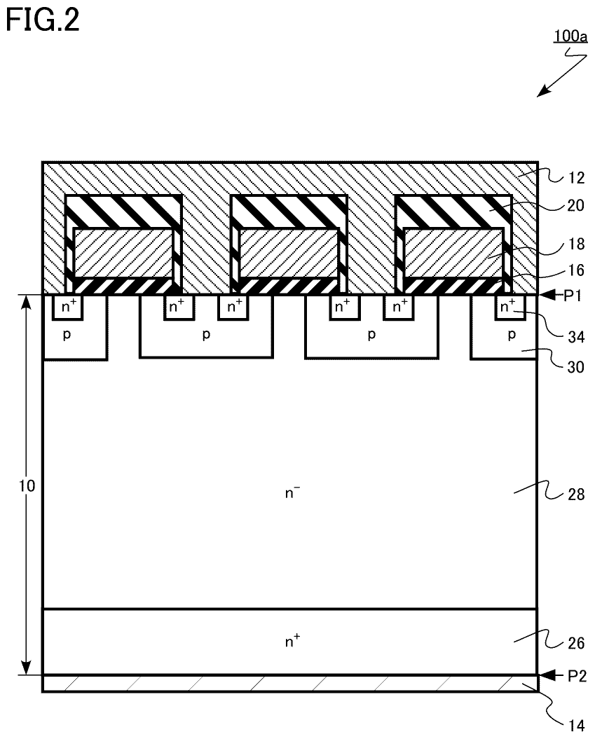

FIG. 2 is a schematic cross-sectional view of the transistor according to the first embodiment. FIG. 2 is a cross-sectional view of the transistor 100a.

The transistor 100a is a planar gate type vertical MOSFET using silicon carbide. The transistor 100a is, for example, a double implantation MOSFET (DIMOSFET) in which a body region and a source region are formed by ion implantation. The transistor 100a is a vertical n-channel MOSFET using electrons as carriers. The transistor 100a includes a silicon carbide

layer 10, a source electrode 12 (first electrode), a drain electrode 14 (second electrode), a gate insulating layer 16, a gate electrode 18, and an interlayer insulating layer 20.

In the silicon carbide layer 10, an n⁺-type drain region 26, an n⁻-type drift region 28 (first semiconductor region), a p-type body region 30 (second semiconductor region), and an n⁺-type source region 34 (third semiconductor region) are provided.

The silicon carbide layer 10 is provided between the source electrode 12 and the drain electrode 14. The silicon carbide layer 10 is provided between the gate electrode 18 and the drain electrode 14. The silicon carbide layer 10 is single crystal SiC. The silicon carbide layer 10 is, for example, 4H-SiC.

The silicon carbide layer 10 includes a first plane (“P1” in FIG. 2) and a second plane (“P2” in FIG. 2). The first plane P1 and the second plane P2 face each other. Hereinafter, the first plane is also referred to as a surface and the second plane is also referred to as a back surface. Hereinafter, the “depth” means a depth based on the first plane.

The first plane P1 is, for example, a plane inclined by 0° or more and 8° or less with respect to a (0001) face. Further, the second plane P2 is, for example, a plane inclined by 0° or more and 8° or less with respect to a (000-1) face. The (0001) face is referred to as a silicon face. The (000-1) face is referred to as a carbon face.

The n⁺-type drain region 26 is provided between the source electrode 12 and the drain electrode 14. The n⁺-type drain region 26 is provided at the back surface side of the silicon carbide layer 10. The drain region 26 includes nitrogen (N) as n-type impurities, for example. An n-type impurity concentration of the drain region 26 is, for example, equal to or more than 1×10¹⁸ cm⁻³ and equal to or less than 1×10²¹ cm⁻³.

The drain region 26 is electrically connected to the drain electrode 14. The drain region 26 contacts the drain electrode 14.

The n⁻-type drift region 28 is provided between the drain region 26 and the first plane P1. The drift region 28 is provided between the source electrode 12 and the drain electrode 14. The drift region 28 is provided between the gate electrode 18 and the drain electrode 14.

The drift region 28 functions as a current path when the transistor 100a is in an on state. When the transistor 100a is in an off state, a thick depletion layer is formed in the drift region 28, so that the breakdown voltage of the transistor 100a increases. In addition, the drift region 28 functions as an n-type semiconductor region of a pn junction diode.

The drift region 28 is provided on the drain region 26. The drift region 28 includes nitrogen (N) as n-type impurities, for example. An n-type impurity concentration of the drift region 28 is lower than the n-type impurity concentration of the drain region 26. An n-type impurity concentration of the drift region 28 is, for example, equal to or more than 4×10¹⁴ cm⁻³ and equal to or less than 1×10¹⁷ cm⁻³.

The thickness of the drift region 28 in a direction from the source electrode 12 toward the drain electrode 14 is, for example, equal to or more than 5 μm and equal to or less than 150 μm. The thickness of the drift region 28 in the direction from the source electrode 12 toward the drain electrode 14 is larger than the thickness of the body region 30 in the direction from the source electrode 12 toward the drain electrode 14, for example. The thickness of the drift region 28 in the direction from the source electrode 12 toward the drain electrode 14 is, for example, 10 times or more the thickness of the body region 30 in the direction from the source electrode 12 toward the drain electrode 14.

The drift region 28 is electrically connected to the drain electrode 14.

The p-type body region 30 is provided between the drift region 28 and the first plane P1. The body region 30 is provided between the drift region 28 and the source electrode 12. A part of the body region 30 functions as a channel region of the transistor 100a. The body region 30 functions as a p-type semiconductor region of a pn junction diode.

The body region 30 includes aluminum (Al) as p-type impurities, for example. A p-type impurity concentration of the body region 30 is, for example, equal to or more than 1×10¹⁶ cm⁻³ and equal to or less than 1×10²¹ cm⁻³.

The depth of the body region 30 is, for example, equal to or more than 0.3 μm and equal to or less than 1.0 μm.

The body region 30 is electrically connected to the source electrode 12. The body region 30 contacts the source electrode 12.

The n⁺-type source region 34 is provided between the body region 30 and the first plane P1. The source region 34 is provided between the body region 30 and the source electrode 12.

The source region 34 includes phosphorus (P) as n-type impurities, for example. An n-type impurity concentration of the source region 34 is higher than the n-type impurity concentration of the drift region 28. The n-type impurity concentration of the source region 34 is, for example, 10 times or more the n-type impurity concentration of the drift region 28.

The n-type impurity concentration of the source region 34 is, for example, equal to or more than 1×10¹⁸ cm⁻³ and equal to or less than 1×10²¹ cm⁻³. The depth of the source region 34 is shallower than the depth of the body region 30. The depth of the source region 34 is, for example, equal to or more than 0.1 μm and equal to or less than 0.3 μm.

The source region 34 is electrically connected to the source electrode 12. The source region 34 contacts the source electrode 12.

The gate electrode 18 is provided on the side of the first plane P1 of the silicon carbide layer 10. The gate electrode 18 is provided on the silicon carbide layer 10. The gate electrode 18 has, for example, a stripe shape.

The gate electrode 18 is a conductive layer. The gate electrode 18 is, for example, polycrystalline silicon including p-type impurities or n-type impurities.

The gate electrode 18 faces, for example, a portion of the body region 30 contacting the first plane P1. The gate electrode 18 faces, for example, a portion of the drift region 28 contacting the first plane P1.

The gate insulating layer 16 is provided between the gate electrode 18 and the body region 30. The gate insulating layer 16 is provided between the gate electrode 18 and the drift region 28.

The gate insulating layer 16 is, for example, silicon oxide. For example, a high-k insulating material (high dielectric constant insulating material) can be applied to the gate insulating layer 16.

The interlayer insulating layer 20 is provided on the gate electrode 18 and the silicon carbide layer 10. The interlayer insulating layer 20 is provided between the gate electrode 18 and the source electrode 12. The interlayer insulating layer 20 is, for example, silicon oxide.

The source electrode 12 is provided on the side of the first plane P1 of the silicon carbide layer 10. The source electrode 12 contacts the first plane P1.

The source electrode 12 contacts the body region 30 and the source region 34.

The source electrode 12 includes a metal. The metal forming the source electrode 12 has a stacked structure of titanium (Ti) and aluminum (Al), for example.

A portion of the source electrode 12 contacting the body region 30 and the source region 34 is, for example, metal silicide. The metal silicide is, for example, titanium silicide or nickel silicide.

The contact between the body region 30 and the source electrode 12 and the contact between the source region 34 and the source electrode 12 are, for example, ohmic contact.

The drain electrode 14 is provided on the side of the second plane P2 of the silicon carbide layer 10. The drain electrode 14 contacts the second plane P2. The drain electrode 14 contacts the drain region 26.

The drain electrode 14 is, for example, a metal or a metal semiconductor compound. The drain electrode 14 includes at least one material selected from the group consisting of nickel silicide, titanium (Ti), nickel (Ni), silver (Ag), and gold (Au), for example.

The contact between the drain region 26 and the drain electrode 14 is, for example, ohmic contact.

As illustrated in FIG. 1, a pn junction diode is connected as a built-in diode between the source electrode 12 and the drain electrode 14 of the transistor 100a.

For example, a case where the transistor 100a is used as a switching element connected to an inductive load will be considered. When the transistor 100a is in an off state, a positive voltage higher than a voltage of the drain electrode 14 may be applied to the source electrode 12 due to a load current caused by the inductive load. In this case, a forward current flows through the built-in diode of the transistor 100a. This state is also referred to as a reverse conduction state.

When the voltage between the source electrode 12 and the drain electrode 14 exceeds a forward voltage (Vf) of the pn junction diode, a forward current flows through the pn junction diode.

The ammeter 100b is provided, for example, between the source electrode 12 of the transistor 100a and the channel region. The ammeter 100b is an example of a detector. The ammeter 100b detects a current flowing from the source electrode 12 to the drain electrode 14 in a state where the voltage of the source electrode 12 is a positive voltage higher than the voltage of the drain electrode 14.

The comparison circuit 100c is electrically connected to the ammeter 100b. In a state where the voltage of the source electrode 12 is a positive voltage higher than the voltage of the drain electrode 14, the comparison circuit 100c compares a measurement value measured by the ammeter 100b with a first threshold.

The measurement value measured by the ammeter 100b is a current value. The first threshold is a preset threshold current.

The first threshold is, for example, 0.6 times or more and 1.0 times or less a maximum allowable peak current value (I_{FSM}) of the transistor 100a. The maximum allowable peak current value (I_{FSM}) of the transistor 100a in this case is the maximum allowable peak current value (I_{FSM}) Of the transistor 100a under an operation condition that a gate voltage Vg of +15 V is continuously applied to the gate electrode 18 in a state where the voltage of the source electrode 12 is a positive voltage higher than the voltage of the drain electrode 14.

The comparison circuit 100c is, for example, an electronic circuit. The comparison circuit 100c includes, for example, hardware and software.

The comparison circuit 100c includes, for example, a central processing unit (CPU). The comparison circuit 100c includes, for example, a storage device. The storage device included in the comparison circuit 100c is, for example, a semiconductor memory. For example, the first threshold is stored in the storage device.

The gate driver circuit 100d is electrically connected to the comparison circuit 100c and the gate electrode 18.

In a state where the voltage of the source electrode 12 is a positive voltage higher than the voltage of the drain electrode 14, the gate driver circuit 100d applies a first positive voltage higher than the threshold voltage of the transistor 100a to the gate electrode 18. In addition, the gate driver circuit 100d applies a first negative voltage to the gate electrode 18 when the measurement value exceeds the first threshold in the comparison circuit 100c.

The gate driver circuit 100d is, for example, an electronic circuit. The comparison circuit 100c includes, for example, hardware and software.

In a case where the comparison circuit 100c detects the current flowing from the source electrode 12 to the drain electrode 14, a delay time from when the measurement value exceeds the first threshold in the comparison circuit 100c to when the first negative voltage is applied to the gate electrode 18 is, for example, less than 2 ms (2000 μs). For example, the time from when the measurement value exceeds the first threshold in the comparison circuit 100c to when the gate driver circuit 100d outputs the first negative voltage to the gate electrode 18 is, for example, less than 2 ms.

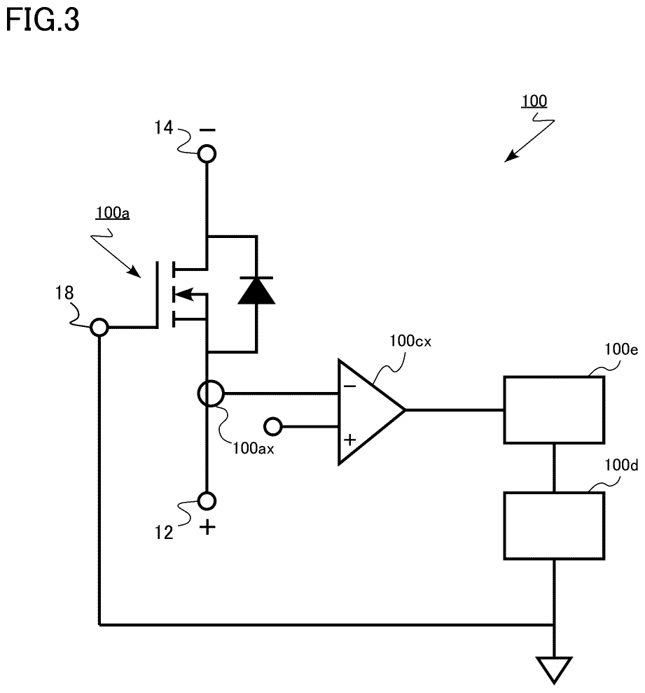

FIG. 3 is a diagram illustrating a specific example of the semiconductor device according to the first embodiment.

The semiconductor module 100 includes a transistor 100a, a Rogowski coil ammeter 100ax, a comparator 100cx, a pulse generator 100e, and a gate driver circuit 100d.

The Rogowski coil ammeter 100ax is an example of a detector. The comparator 100cx is an example of a comparison circuit.

The comparator 100cx compares a magnitude relationship between the measurement value measured by the Rogowski coil ammeter 100ax and the first threshold. The pulse generator 100e generates a pulse based on a comparison result by the comparator 100cx and transmits the pulse to the gate driver circuit 100d.

Next, a method of controlling the semiconductor device according to the first embodiment will be described.

The method of controlling the semiconductor device according to the first embodiment is a method of controlling a semiconductor device including a transistor, the transistor including a first electrode, a second electrode, an n-type first semiconductor region provided between the first electrode and the second electrode and electrically connected to the second electrode, a p-type second semiconductor region provided between the first semiconductor region and the first electrode and electrically connected to the first electrode, an n-type third semiconductor region provided between the second semiconductor region and the first electrode and electrically connected to the first electrode, and a gate electrode facing the second semiconductor region. The method includes: applying a positive voltage higher than a voltage of the second electrode to the first electrode; applying a first positive voltage higher than a threshold voltage of the transistor to the gate electrode; detecting a current flowing from the first electrode to the second electrode; and comparing a detected measurement value with a first threshold, and applying a first negative voltage to the gate electrode when the measurement value exceeds the first threshold.

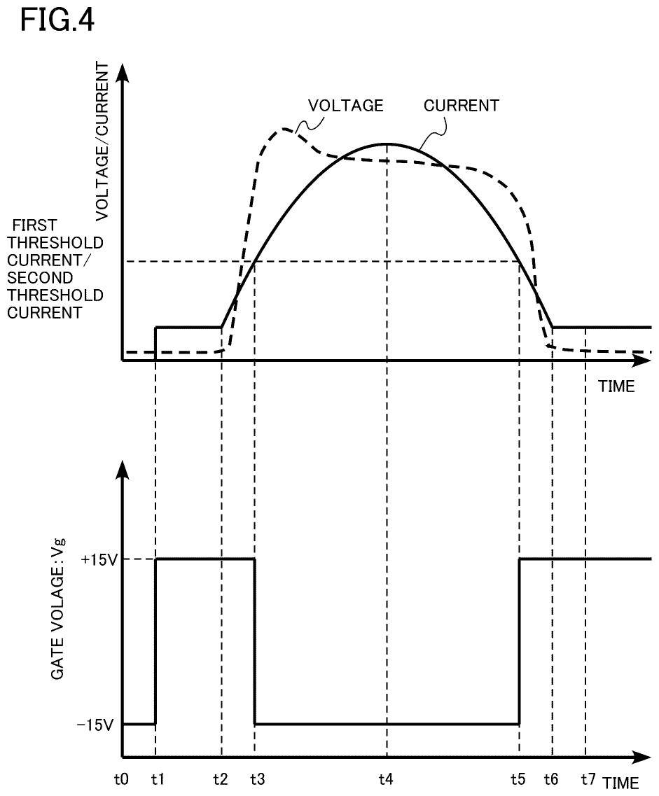

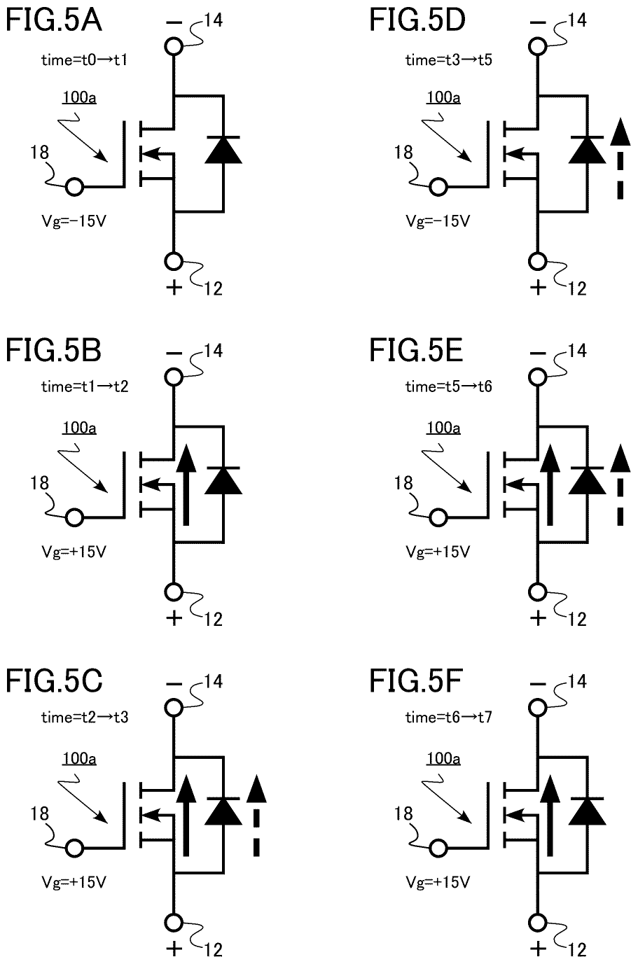

FIGS. 4, 5A, 5B, 5C, 5D, 5E, and 5F are explanatory diagrams of the method of controlling the semiconductor device according to the first embodiment.

FIG. 4 is a diagram illustrating temporal changes of the current and the gate voltage of the transistor 100a according to the first embodiment. FIG. 4 illustrates temporal changes of the current and the gate voltage in a state where the voltage of the source electrode 12 is a positive voltage higher than the voltage of the drain electrode 14. FIG. 4 also illustrates the voltage of the source electrode 12.

In an upper diagram of FIG. 4, a horizontal axis represents the time, and a vertical axis represents the current and the voltage. The current is a current flowing from the source electrode 12 to the drain electrode 14. The voltage is a voltage of the source electrode 12. Note that the voltage of the source electrode 12 is, for example, an electric potential difference between an electric potential of the source electrode 12 and a reference electric potential. The reference electric potential is, for example, 0 V. In the upper diagram of FIG. 4, the current is indicated by a solid line, and the voltage is indicated by a dotted line.

In a lower diagram of FIG. 4, a horizontal axis represents the time, and a vertical axis represents the gate voltage. The gate voltage is a voltage to be applied to the gate electrode 18. The gate voltage is, for example, an electric potential difference between the electric potential of the gate electrode 18 and the reference electric potential. The reference electric potential is, for example, 0 V.

FIGS. 5A, 5B, 5C, 5D, 5E, and 5F are schematic diagrams illustrating a current flowing through the transistor 100a for each time illustrated in FIG. 4. In the drawings, a solid arrow indicates a unipolar current, and a dotted arrow indicates a bipolar current.

Note that, in the following description, for example, a case where the transistor 100a is a high-side transistor provided in one arm of a three-phase inverter circuit that performs a synchronous rectification operation is considered as an example. In particular, a case where a voltage that is positive with respect to the drain electrode 14 is applied to the source electrode 12 due to the load current caused by the inductive load when the transistor 100a is in an off state is considered. In other words, a case where the source voltage of the source electrode 12 is a positive voltage higher than the drain voltage of the drain electrode 14 is considered.

Between time t0 and time t1, a gate voltage Vg lower than the threshold voltage of the transistor 100a is applied to the gate electrode 18. Between time t0 and time t1, for example, a negative gate voltage Vg is applied to the gate electrode 18. Between time t0 and time t1, a negative voltage is applied to the gate electrode 18. The gate voltage Vg is, for example, −15 V.

The gate voltage Vg is applied to the gate electrode 18 by the gate driver circuit 100d.

Between time t0 and time t1, the gate voltage Vg is lower than the threshold voltage of the transistor 100a. Therefore, between time t0 and time t1, as illustrated in FIG. 5A, no inversion layer is formed in the channel region of the transistor 100a, and no current flows in the channel region. Between time t0 and time t1, for example, the voltage between the source electrode 12 and the drain electrode 14 is lower than the forward voltage (Vf) of the pn junction diode built in the transistor 100a, so that no current flows through the pn junction diode.

In the three-phase inverter circuit that performs the synchronous rectification operation, it is necessary to prevent a through current from flowing through one arm. For example, it is necessary to prevent the through current from flowing when both the low-side transistor provided in the same arm as the transistor 100a and the transistor 100a are turned on. Therefore, in the synchronous rectification operation, there is provided a dead time in which both the low-side transistor and the transistor 100a which is the high-side transistor are turned off. A part of the dead time is from time t0 to time t1.

Between time t1 and time t2, a positive gate voltage Vg is applied to the gate electrode 18. Between time t1 and time t2, a positive voltage is applied to the gate electrode 18. The gate voltage Vg is, for example, +15 V. Between time t1 and time t2, the gate voltage Vg to be applied to the gate electrode 18 is an example of a first positive voltage.

Between time t1 and time t2, as illustrated in FIG. 5B, an inversion layer is formed in the channel region of the transistor 100a, and a unipolar current flows through the channel region. Between time t1 and time t2, for example, the voltage between the source electrode 12 and the drain electrode 14 is lower than the forward voltage (Vf) of the pn junction diode built in the transistor 100a, so that no current flows through the pn junction diode.

For example, between time t2 and time t6, a large surge current exceeding a steady state flows through the transistor 100a. For example, the surge current is maximized at time t4. Between time t0 and time t2 and between time t6 and time t7, the transistor 100a is in a steady state.

Between time t2 and time t3, the positive gate voltage Vg is applied to the gate electrode 18. Between time t2 and time t3, a positive voltage is applied to the gate electrode 18. The gate voltage Vg is, for example, +15 V. Between time t2 and time t3, the gate voltage Vg to be applied to the gate electrode 18 is an example of the first positive voltage.

Between time t2 and time t3, as illustrated in FIG. 5C, an inversion layer is formed in the channel region of the transistor 100a, and a unipolar current flows through the channel region. Between time t2 and time t3, for example, the voltage between the source electrode 12 and the drain electrode 14 becomes higher than the forward voltage (Vf) of the pn junction diode built in the transistor 100a, and a bipolar current flows through the pn junction diode. Between time t2 and time t3, for example, the unipolar current and the bipolar current flow through the transistor 100a.

At time t3, the current flowing from the source electrode 12 to the drain electrode 14 of the transistor 100a exceeds the first threshold current. The first threshold current is a predetermined current value. The first threshold current is an example of the first threshold. The current flowing from the source electrode 12 to the drain electrode 14 is measured by the ammeter 100b.

The first threshold current is, for example, 0.6 times or more and 1.0 times or less the maximum allowable peak current value (I_{FSM}) of the transistor 100a. The maximum allowable peak current value (I_{FSM}) of the transistor 100a in this case is the maximum allowable peak current value (I_{FSM}) Of the transistor 100a under an operation condition that a gate voltage Vg of +15 V is continuously applied to the gate electrode 18 in a state where the voltage of the source electrode 12 is a positive voltage higher than the voltage of the drain electrode 14.

At time t3, the comparison circuit 100c determines that the current flowing from the source electrode 12 to the drain electrode 14 of the transistor 100a exceeds the first threshold current. The comparison circuit 100c makes a determination by comparing the measurement value measured by the ammeter 100b with the first threshold current.

At time t3, a negative gate voltage Vg lower than the threshold voltage of the transistor 100a is applied to the gate electrode 18. At time t3, a negative voltage is applied to the gate electrode 18. The gate voltage Vg is, for example, −15 V. At time t3, the gate voltage Vg to be applied to the gate electrode 18 is an example of the first negative voltage.

As a result of the comparison in the comparison circuit 100c, when the measurement value of the current exceeds the first threshold current, the first negative voltage is applied to the gate electrode 18 by the gate driver circuit 100d.

The delay time from when the measurement value exceeds the first threshold current in the comparison circuit 100c to when the negative voltage is applied to the gate electrode 18 is, for example, equal to or less than 2 ms. For example, the time from when the measurement value exceeds the first threshold current in the comparison circuit 100c to when the gate driver circuit 100d outputs the first negative voltage to the gate electrode 18 is, for example, equal to or less than 2 ms.

Between time t3 and time t5, a negative gate voltage Vg is applied to the gate electrode 18. Between time t3 and time t5, a negative voltage is applied to the gate electrode 18. The gate voltage Vg is, for example, −15 V. Between time t3 and time t5, the gate voltage Vg to be applied to the gate electrode 18 is an example of the first negative voltage.

Between time t3 and time t5, the gate voltage Vg becomes the first negative voltage, so that the body region 30 facing the gate electrode 18 is in an accumulation state. Between time t3 and time t5, an accumulation layer is formed in the channel region of the transistor 100a, and no channel is formed in the channel region. Therefore, as illustrated in FIG. 5D, no current flows through the channel region.

Between time t3 and time t5, for example, the voltage between the source electrode 12 and the drain electrode 14 becomes higher than the forward voltage (Vf) of the pn junction diode built in the transistor 100a, and a bipolar current flows through the pn junction diode. Between time t3 and time t5, for example, the unipolar current does not flow and only the bipolar current flows.

At time t5, the current flowing from the source electrode 12 to the drain electrode 14 of the transistor 100a falls below a second threshold current. The second threshold current is an example of a second threshold. The second threshold current may be equal to the first threshold current. The second threshold current may be different from the first threshold current.

At time t5, the comparison circuit 100c determines that the current flowing from the source electrode 12 to the drain electrode 14 of the transistor 100a falls below the second threshold current. The comparison circuit 100c makes a determination by comparing the measurement value measured by the ammeter 100b with the second threshold current.

At time t5, a positive gate voltage Vg higher than the threshold voltage of the transistor 100a is applied to the gate electrode 18. At time t5, a positive voltage is applied to the gate electrode 18. The gate voltage Vg is, for example, +15 V. At time t5, the gate voltage Vg to be applied to the gate electrode 18 is an example of a second positive voltage.

As a result of the comparison in the comparison circuit 100c, when the measurement value of the current falls below the second threshold current, the second positive voltage is applied to the gate electrode 18 by the gate driver circuit 100d.

Between time t5 and time t6, a positive gate voltage Vg is applied to the gate electrode 18. Between time t5 and time t6, a positive voltage is applied to the gate electrode 18. The gate voltage Vg is, for example, +15 V. Between time t5 and time t6, the gate voltage Vg to be applied to the gate electrode 18 is an example of the second positive voltage.

Between time t5 and time t6, an inversion layer is formed in the channel region of the transistor 100a. Therefore, as illustrated in FIG. 5E, a unipolar current flows through the channel region of the transistor 100a. Between time t5 and time t6, for example, the voltage between the source electrode 12 and the drain electrode 14 is higher than the forward voltage (Vf) of the pn junction diode built in the transistor 100a. Therefore, a bipolar current flows through the pn junction diode. Between time t5 and time t6, for example, the unipolar current and the bipolar current flow through the transistor 100a.

Between time t6 and time t7, a positive gate voltage Vg is applied to the gate electrode 18. Between time t6 and time t7, a positive voltage is applied to the gate electrode 18. The gate voltage Vg is, for example, +15 V. Between time t6 and time t7, the gate voltage Vg to be applied to the gate electrode 18 is an example of the second positive voltage.

Between time t6 and time t7, an inversion layer is formed in the channel region of the transistor 100a. Therefore, as illustrated in FIG. 5F, a unipolar current flows through the channel region of the transistor 100a. Between time t6 and time t7, for example, the voltage between the source electrode 12 and the drain electrode 14 is lower than the forward voltage (Vf) of the pn junction diode built in the transistor 100a, so that no current flows through the pn junction diode.

Next, functions and effects of the semiconductor device according to the first embodiment will be described.

A vertical MOSFET using silicon carbide includes a pn junction diode as a built-in diode. For example, the MOSFET is used as a switching element connected to an inductive load. In this case, even when the MOSFET is in an off state, a reflux current can be caused to flow by using the built-in diode.

A large surge current may flow through the MOSFET instantaneously beyond a steady state. When the large surge current flows, the MOSFET generates heat and breaks down. The maximum allowable peak current value (I_{FSM}) of the surge current allowed in the MOSFET is referred to as a surge current resistance. In the MOSFET, it is desired to improve the surge current resistance.

In the semiconductor module 100 of the first embodiment, when the surge current flows through the transistor 100a included in the semiconductor module 100, the negative voltage is applied to the gate electrode 18, so that the surge current resistance can be improved. The details will be described below.

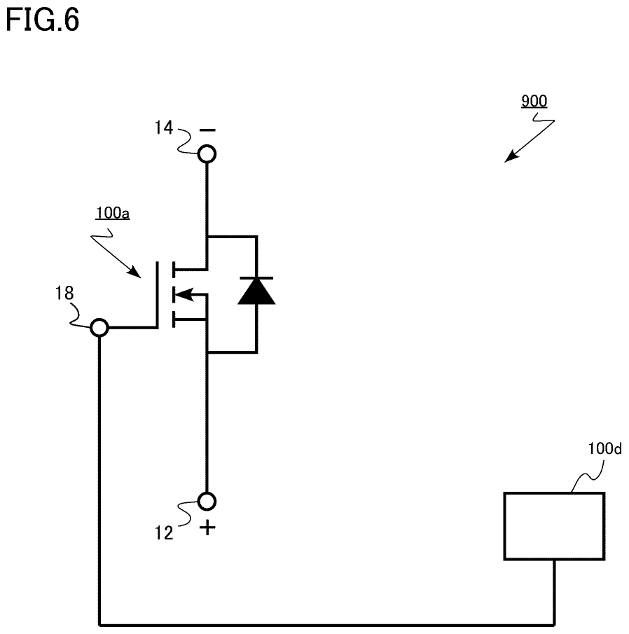

FIG. 6 is a block diagram of a semiconductor device according to a comparative example. The semiconductor device according to the comparative example is a semiconductor module 900 including the transistor 100a using silicon carbide.

The semiconductor module 900 includes the transistor 100a and the gate driver circuit 100d. The semiconductor module 900 is different from the semiconductor module 100 according to the first embodiment in that the ammeter 100b and the comparison circuit 100c are not included.

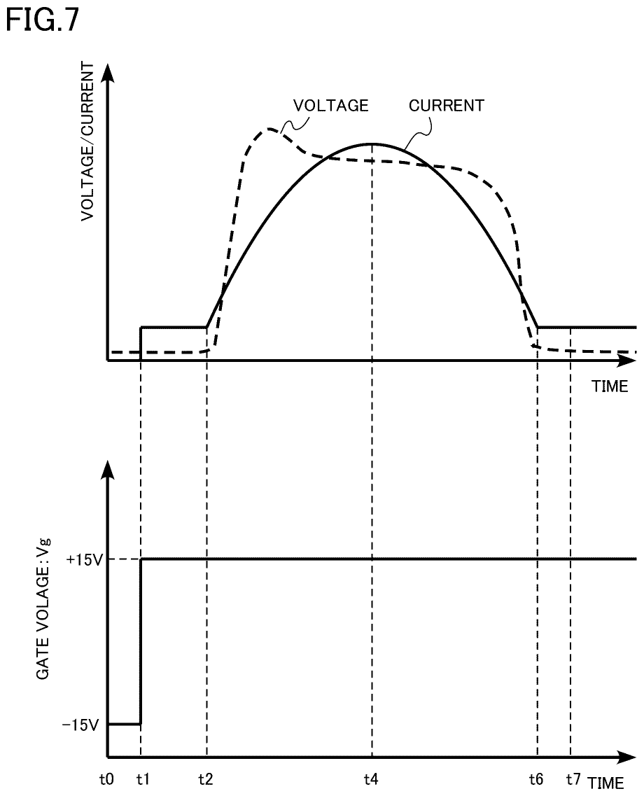

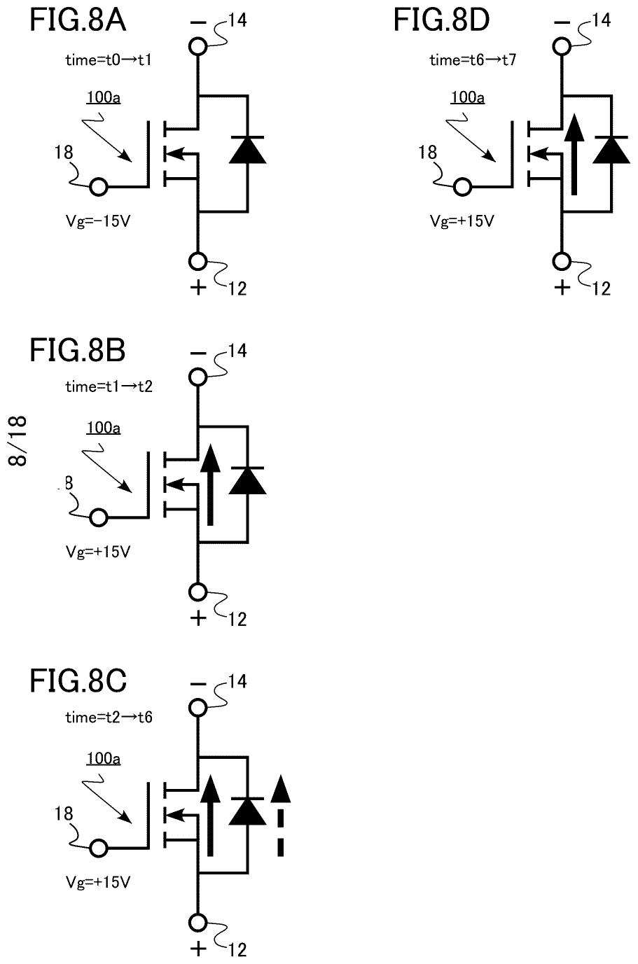

FIGS. 7, 8A, 8B, 8C, and 8D are explanatory diagrams of a method of controlling a semiconductor device according to the comparative example.

FIG. 7 is a diagram illustrating temporal changes of the current and the gate voltage of the transistor 100a according to the comparative example. FIG. 7 is a diagram corresponding to FIG. 4 illustrating the first embodiment.

FIGS. 8A, 8B, 8C, and 8D are schematic diagrams illustrating the current flowing through the transistor 100a for each time illustrated in FIG. 7. In the drawings, a solid arrow indicates a unipolar current, and a dotted arrow indicates a bipolar current.

Between time t0 and time t1, a gate voltage Vg lower than the threshold voltage of the transistor 100a is applied to the gate electrode 18. Between time t0 and time t1, as illustrated in FIG. 8A, no current flows through the channel region. Between time t0 and time t1, for example, no current flows through the pn junction diode.

Between time t1 and time t2, a positive gate voltage Vg higher than the threshold voltage of the transistor 100a is applied to the gate electrode 18. Between time t1 and time t2, as illustrated in FIG. 8B, the unipolar current flows through the channel region. Between time t1 and time t2, no current flows through the pn junction diode.

For example, between time t2 and time t6, as illustrated in an upper diagram of FIG. 7, a large surge current exceeding a steady state is applied to the transistor 100a. For example, the surge current is maximized at time t4.

Between time t2 and time t6, as illustrated in a lower diagram of FIG. 7, a positive gate voltage Vg higher than the threshold voltage of the transistor 100a is applied to the gate electrode 18. Between time t2 and time t6, a positive voltage is applied to the gate electrode 18. The gate voltage Vg is, for example, +15 V.

Between time t2 and time t6, an inversion layer is formed in the channel region of the transistor 100a. Therefore, as illustrated in FIG. 8C, a unipolar current flows in the channel region of the transistor 100a. Between time t2 and time t6, for example, the voltage between the source electrode 12 and the drain electrode 14 is higher than the forward voltage (Vf) of the pn junction diode built in the transistor 100a. Therefore, a bipolar current flows through the pn junction diode. Between time t2 and time t6, for example, the unipolar current and the bipolar current flow through the transistor 100a.

Between time t6 and time t7, a positive gate voltage Vg is applied to the gate electrode 18. Between time t1 and time t2, an inversion layer is formed in the channel region of the transistor 100a. Therefore, as illustrated in FIG. 8D, the unipolar current flows through the channel region. Between time t6 and time t7, for example, the voltage between the source electrode 12 and the drain electrode 14 is lower than the forward voltage (Vf) of the pn junction diode built in the transistor 100a, so that no current flows through the pn junction diode.

A method of controlling the semiconductor module 900 according to the comparative example is different from the method of controlling the semiconductor module 100 according to the first embodiment in that a negative voltage is not applied to the gate electrode 18 particularly when a large surge current flows through the transistor 100a. In other words, the method of controlling the semiconductor module 900 according to the comparative example is different from the method of controlling the semiconductor module 100 according to the first embodiment in that a positive voltage is continuously applied to the gate electrode 18 particularly when a large surge current flows through the transistor 100a.

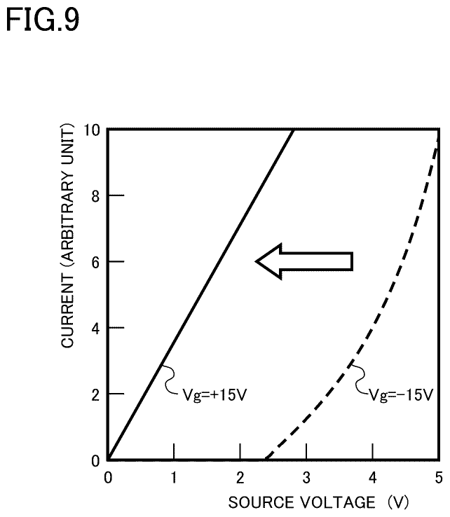

FIG. 9 is an explanatory diagram of functions and effects of the semiconductor device according to the first embodiment. FIG. 9 illustrates a relationship between the source voltage of the transistor 100a and the current flowing through the transistor 100a. The current is a current flowing in a state where the source voltage of the source electrode 12 is a positive voltage higher than the drain voltage of the drain electrode 14. A solid line in FIG. 9 indicates a case where the gate voltage Vg is +15 V, and a dotted line indicates a case where the gate voltage Vg is −15 V.

As illustrated in FIG. 9, in a case where the gate voltage Vg is +15 V, since the unipolar current flows through the channel region of the transistor 100a, the current rises from the source voltage 0 V. On the other hand, as illustrated in FIG. 9, in a case where the gate voltage Vg is −15 V, no current flows through the channel region of the transistor 100a, and the current rises when the source voltage exceeds the forward voltage (Vf) of the pn junction diode.

When the reflux current is caused to flow using the transistor 100a, for example, the unipolar current is caused to flow through the channel region with the gate voltage Vg set to +15 V, whereby the power loss of the semiconductor module can be reduced. Therefore, in a case of flowing the reflux current, it is preferable to apply a positive voltage exceeding the threshold voltage of the transistor 100a as the gate voltage Vg.

In the semiconductor module 900 according to the comparative example, a positive voltage exceeding the threshold voltage of the transistor 100a is applied as the gate voltage Vg during a period of a steady state where no surge current flows, for example, between time t1 and time t2 and between time t6 and time t7. Therefore, the power loss of the semiconductor module 900 can be reduced.

Similarly, in the semiconductor module 100 according to the first embodiment, a positive voltage exceeding the threshold voltage of the transistor 100a is applied as the gate voltage Vg during a period of a steady state where no surge current flows, for example, between time t1 and time t2 and between time t6 and time t7. Therefore, the power loss of the semiconductor module 100 can be reduced.

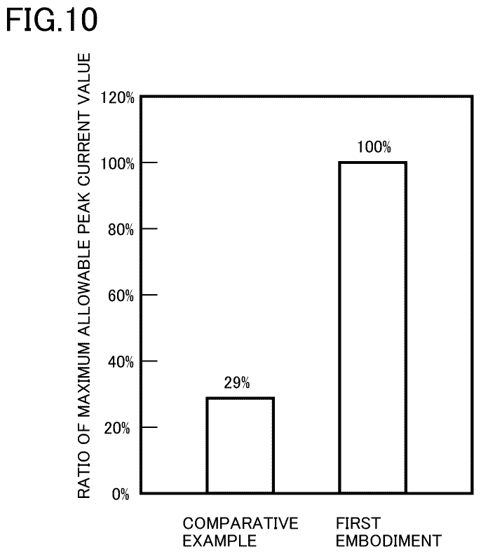

FIG. 10 is an explanatory diagram of functions and effects of the semiconductor device according to the first embodiment. FIG. 10 illustrates a ratio of the maximum allowable peak current value (I_{FSM}) of each of the semiconductor modules of the comparative example and the first embodiment. FIG. 10 illustrates a ratio of the maximum allowable peak current value (I_{FSM}) of the semiconductor module of the comparative example when the maximum allowable peak current value (I_{FSM}) of the semiconductor module of the first embodiment is 100%.

As illustrated in FIG. 10, the ratio of the maximum allowable peak current value (I_{FSM}) of the semiconductor module of the comparative example is 29%, which is lower than the maximum allowable peak current value (I_{FSM}) of the semiconductor module of the first embodiment. In other words, the semiconductor module of the first embodiment has an improved surge current resistance as compared with the semiconductor module of the comparative example.

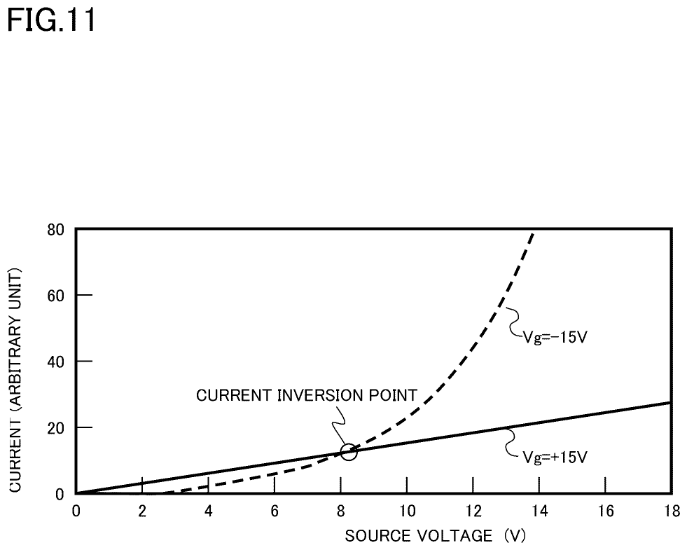

FIG. 11 is an explanatory diagram of functions and effects of the semiconductor device according to the first embodiment. FIG. 11 illustrates a relationship between the source voltage of the transistor 100a and the current flowing through the transistor 100a. The current is a current flowing in a state where the source voltage of the source electrode 12 is a positive voltage higher than the drain voltage of the drain electrode 14. A solid line in

FIG. 11 indicates a case where the gate voltage Vg is +15 V, and a dotted line indicates a case where the gate voltage Vg is −15 V. FIG. 11 is a diagram including a region where the source voltage is higher than that in FIG. 9.

As illustrated in FIG. 11, in a region where the current flowing through the transistor 100a is low, the source voltage is lower when the gate voltage Vg is +15 V than when the gate voltage Vg is −15 V. Therefore, in the case where the gate voltage Vg is +15 V, a calorific value proportional to the product of the current and the voltage is suppressed to be low.

On the other hand, as illustrated in FIG. 11, in a region where the current flowing through the transistor 100a is high, specifically, in a region where the current is higher than a current inversion point in FIG. 11, the source voltage is higher when the gate voltage Vg is +15 V than when the gate voltage Vg is −15 V. Therefore, in the region where the current is higher than the current inversion point in FIG. 11, the calorific value proportional to the product of the current and the voltage is higher when the gate voltage Vg is +15 V than when the gate voltage Vg is −15 V.

In the semiconductor module 900 of the comparative example, as illustrated in FIG. 7, the gate voltage Vg is maintained at +15 V between time t2 and time t6 for which the surge current flows. Therefore, for example, as compared with a case where the gate voltage Vg is maintained at −15 V, the calorific value when the surge current flows increases. Therefore, it is considered that the surge current resistance is lowered.

On the other hand, in the semiconductor module 100 according to the first embodiment, as illustrated in FIG. 4, the gate voltage Vg is maintained at −15 V between time t3 and time t5 for which a high surge current flows. Therefore, for example, as compared with a case where the gate voltage Vg is maintained at +15 V, the calorific value when the surge current flows decreases. Therefore, it is considered that the surge current resistance is improved.

In the semiconductor module 100 of the first embodiment, from the viewpoint of not causing a current to flow through the channel region of the transistor 100a, the first negative voltage applied to the gate electrode 18 between time t3 and time t5 is preferably equal to or less than −5 V, more preferably equal to or less than −10 V, and still more preferably equal to or less than −15 V.

In the semiconductor module 100 of the first embodiment, from the viewpoint of causing a current to flow through the channel region of the transistor 100a, the first negative voltage applied to the gate electrode 18 between time t1 and time t2 and between time t6 and time t7 is preferably equal to or more than +5 V, more preferably equal to or more than +10 V, and still more preferably equal to or more than +15 V.

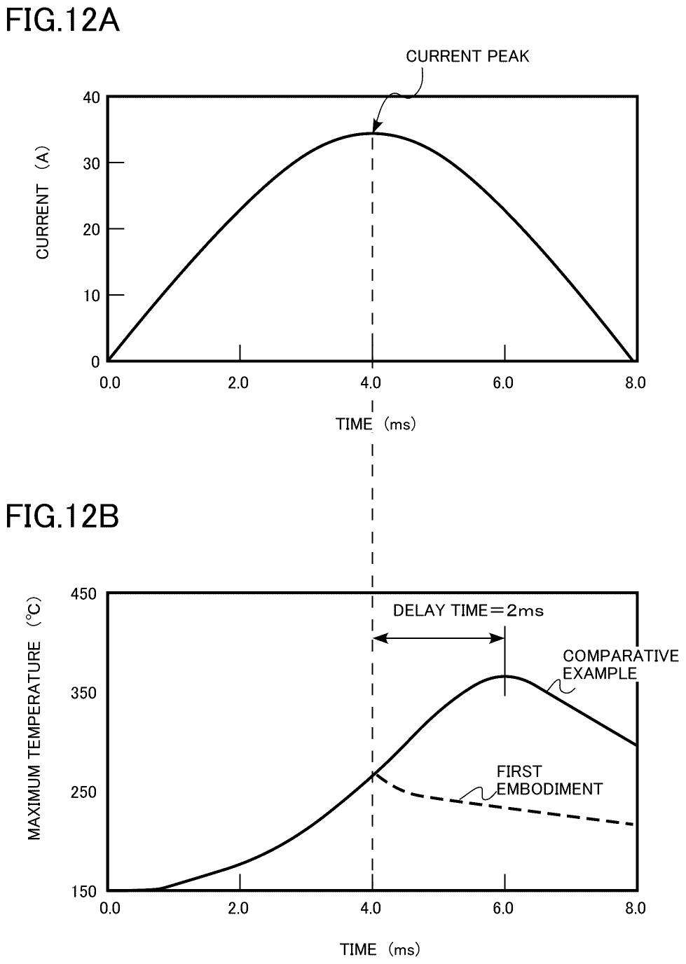

FIGS. 12A and 12B are explanatory diagrams of functions and effects of the semiconductor device according to the first embodiment. FIGS. 12A and 12B are diagrams illustrating simulation results.

FIG. 12A is a diagram illustrating a temporal change of a surge current when +15 V, which is the positive gate voltage Vg higher than the threshold voltage of the transistor 100a, is applied to the gate electrode 18 in the structure of the transistor 100a illustrated in FIG. 2. As illustrated in FIG. 12A, a current peak having a current value of 34 A is observed at a time of 4.0 ms (milliseconds).

FIG. 12B is a diagram illustrating a maximum temperature in the transistor 100a in a state where a surge current flows in the structure of the transistor 100a illustrated in FIG. 2. A solid line indicates a case where +15 V is continuously applied as the gate voltage Vg, similarly the comparative example. A dotted line indicates a case where the voltage is switched from +15 V which is the positive gate voltage Vg to −15 V which is the negative gate voltage Vg at the time (4.0 ms) when the current peak is observed. The dotted line corresponds to the first embodiment.

As illustrated in FIG. 12B, it can be seen that there is a delay of 2 ms (milliseconds) from the time when the current peak is observed to the time when the maximum temperature is shown. A propagation delay of heat inside the transistor 100a is considered to be a cause of the delay time.

Since the delay time exists, the temperature inside the transistor 100a is suppressed to be sufficiently low as indicated by the dotted line in FIG. 12B, even if the gate voltage Vg is switched from the positive voltage to the negative voltage at the same time as the time when the current peak is observed. Since the delay time exists, the temperature inside the transistor 100a can be suppressed from reaching the maximum temperature by switching the gate voltage Vg from the positive voltage to the negative voltage within less than 2 ms from the time when the current peak is observed.

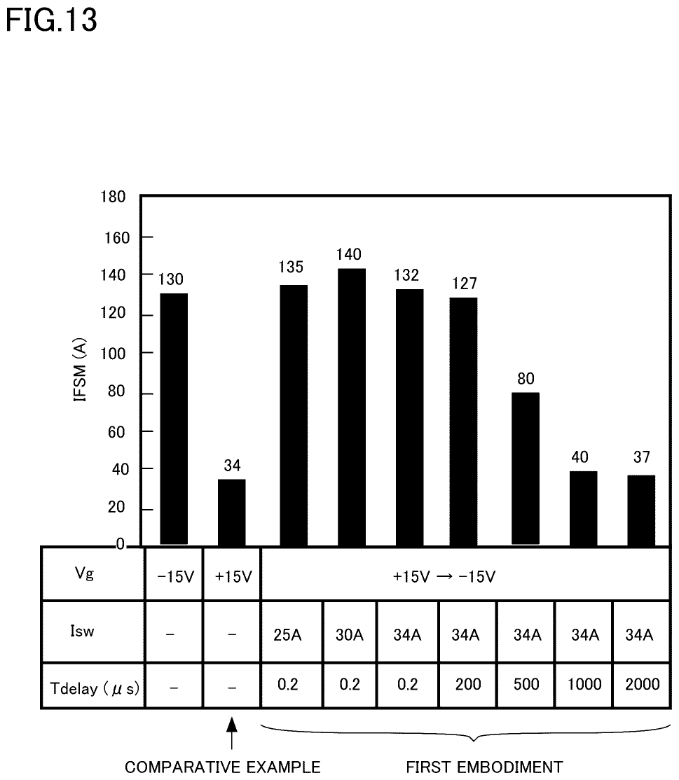

FIG. 13 is an explanatory diagram of functions and effects of the semiconductor device according to the first embodiment. FIG. 13 is a diagram illustrating an experimental result using the transistor 100a illustrated in FIG. 2.

The maximum allowable peak current value (I_{FSM}) Of the transistor 100a is a result of evaluating, as parameters, the gate voltage Vg, the first threshold current (Isw), and the delay time (Tdelay) from when the first threshold current (Isw) is detected to when the first negative voltage which is the negative gate voltage Vg is applied to the gate electrode 18.

When the first threshold current (Isw) is set to 34 A, which is the maximum allowable peak current value (I_{FSM}) under the operation condition of the comparative example, that is, the operation condition that a positive gate voltage of 15 V is continuously applied to the gate electrode 18, under the operation condition of the first embodiment, no decrease in the maximum allowable peak current value (I_{FSM}) is observed from the maximum allowable peak current value (I_{FSM}) under the operation condition that a negative gate voltage of −15 V is continuously applied to the gate electrode 18 until the delay time reaches 200 μs (microseconds). Further, until the delay time reaches 2000 μs (2 ms), a maximum allowable peak current value (I_{FSM}) equal to or more than the maximum allowable peak current value (I_{FSM}) under the operation condition that the positive gate voltage of 15 V is continuously applied to the gate electrode 18 can be realized.

When the comparison circuit 100c detects the current flowing from the source electrode 12 to the drain electrode 14, the delay time from when the measurement value exceeds the first threshold current in the comparison circuit 100c to when the first negative voltage is applied to the gate electrode 18 is preferably less than 2 ms, more preferably less than 500 μs, and still more preferably less than 200 μs. For example, the time from when the measurement value exceeds the first threshold current in the comparison circuit 100c to when the gate driver circuit 100d outputs the first negative voltage to the gate electrode 18 is preferably less than 2 ms, more preferably less than 500 μs, and still more preferably less than 200 μs. The delay time satisfies the above upper limit value, so that a decrease in the maximum allowable peak current value (I_{FSM}) of the transistor 100a is suppressed, and the surge current resistance is improved.

The first threshold current is preferably 0.6 times or more and 1.0 times or less the maximum allowable peak current value (I_{FSM}) of the transistor 100a, and more preferably 0.8 times or more and 1.0 times or less. The maximum allowable peak current value (I_{FSM}) of the transistor 100a in this case is the maximum allowable peak current value (I_{FSM}) of the transistor 100a under the operation condition (the operation condition of the comparative example) that the gate voltage Vg of +15 V is continuously applied to the gate electrode 18 in a state where the voltage of the source electrode 12 is a positive voltage higher than the voltage of the drain electrode 14.

The first threshold current satisfies the above upper limit value, so that a decrease in the maximum allowable peak current value (I_{FSM}) of the transistor 100a is suppressed. In addition, the first threshold current satisfies the above lower limit value, so that reduction of the power loss of the semiconductor module 100 is promoted.

### Modification

A semiconductor device according to a modification of the first embodiment is different from that of the first embodiment in including a detector that detects a voltage of a first electrode in a state where the voltage of the first electrode is a positive voltage higher than the voltage of a second electrode.

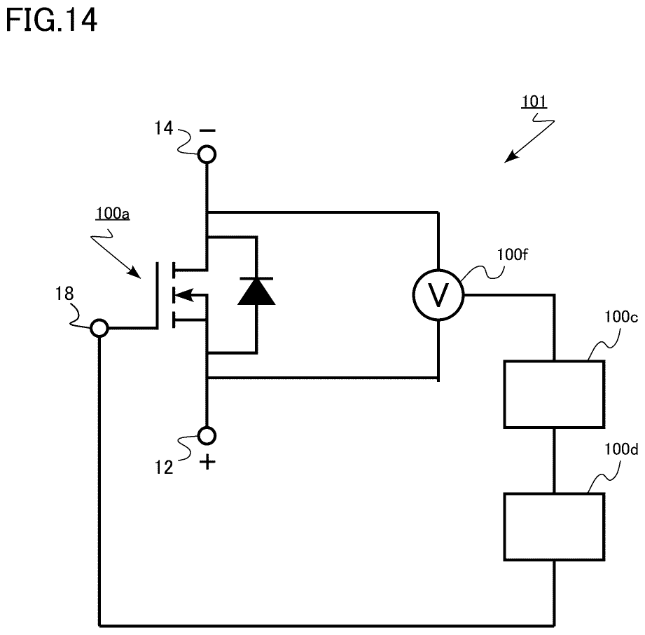

FIG. 14 is a block diagram of the semiconductor device according to the modification of the first embodiment. The semiconductor device according to the modification of the first embodiment is a semiconductor module 101 including a transistor 100a using silicon carbide.

The semiconductor module 101 includes the transistor 100a, a voltmeter 100f, a comparison circuit 100c, and a gate driver circuit 100d.

The voltmeter 100f is provided, for example, between a source electrode 12 and a drain electrode 14 of the transistor 100a. The voltmeter 100f can detect a voltage of the source electrode 12, that is, a source voltage.

The voltmeter 100f is an example of a detector. The voltmeter 100f detects the voltage of the source electrode 12 in a state where the voltage of the source electrode 12 is a positive voltage higher than the voltage of the drain electrode 14.

The comparison circuit 100c is electrically connected to the voltmeter 100f. In a state where the voltage of the source electrode 12 is a positive voltage higher than the voltage of the drain electrode 14, the comparison circuit 100c compares a measurement value measured by the voltmeter 100f with a first threshold.

The measurement value measured by the voltmeter 100f is a voltage value. The first threshold is a preset threshold voltage. The first threshold is, for example, equal to or more than 5 V and equal to or less than 15 V.

The gate driver circuit 100d is electrically connected to the comparison circuit 100c and the gate electrode 18.

In a state where the voltage of the source electrode 12 is a positive voltage higher than the voltage of the drain electrode 14, the gate driver circuit 100d applies a first positive voltage higher than the threshold voltage of the transistor 100a to the gate electrode 18. In addition, the gate driver circuit 100d applies a first negative voltage to the gate electrode 18 when the measurement value exceeds the first threshold in the comparison circuit 100c.

Next, a method of controlling the semiconductor device according to the modification of the first embodiment will be described.

The method of controlling the semiconductor device according to the modification of the first embodiment is different from the method of controlling the semiconductor device according to the first embodiment in that the voltage of the first electrode is detected.

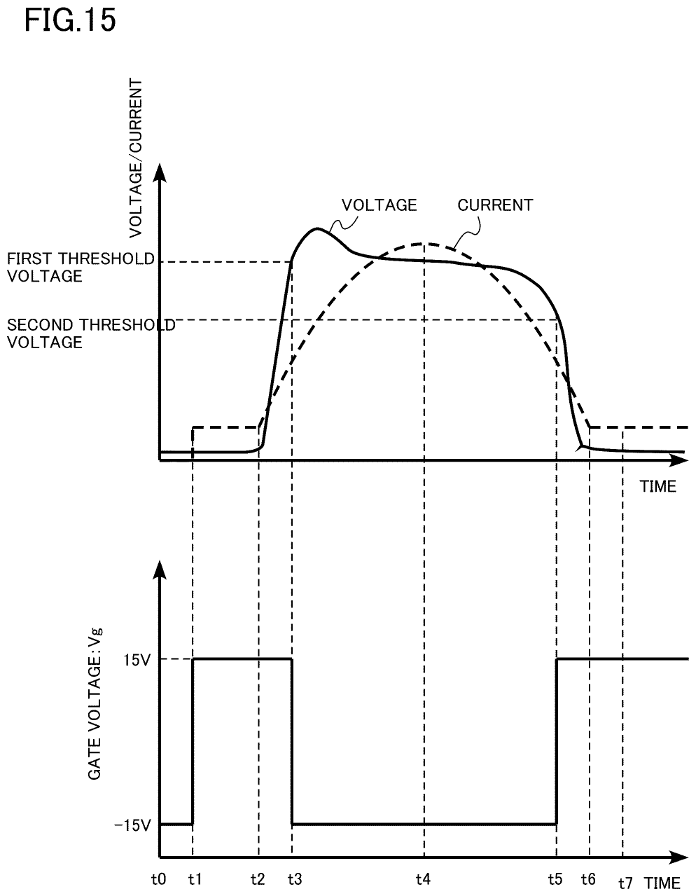

FIG. 15 is an explanatory diagram of the method of controlling the semiconductor device according to the modification of the first embodiment. FIG. 15 is a diagram corresponding to FIG. 4 illustrating the first embodiment.

FIG. 15 is a diagram illustrating temporal changes of the voltage and the gate voltage of the transistor 100a according to the modification of the first embodiment.

FIG. 15 illustrates temporal changes of the voltage and the gate voltage in a state where the voltage of the source electrode 12 is a positive voltage higher than the voltage of the drain electrode 14. FIG. 15 also illustrates the current of the source electrode 12.

In an upper diagram of FIG. 15, a horizontal axis represents the time, and a vertical axis represents the current and the voltage. The current is a current flowing from the source electrode 12 to the drain electrode 14. The voltage is a voltage of the source electrode 12. The reference electric potential is, for example, 0 V. In the upper diagram of FIG. 15, the current is indicated by a dotted line, and the voltage is indicated by a solid line.

In a lower diagram of FIG. 15, a horizontal axis represents the time, and a vertical axis represents the gate voltage. The gate voltage is a voltage to be applied to the gate electrode 18.

Between time t0 and time t1, similarly to the first embodiment, a gate voltage Vg lower than the threshold voltage of the transistor 100a is applied to the gate electrode 18. Between time t0 and time t1, for example, a negative gate voltage Vg is applied to the gate electrode 18.

Between time t1 and time t2, similarly to the first embodiment, a positive gate voltage Vg is applied to the gate electrode 18. Between time t1 and time t2, a positive voltage is applied to the gate electrode 18. The gate voltage Vg is, for example, +15 V. Between time t1 and time t2, the gate voltage Vg to be applied to the gate electrode 18 is an example of a first positive voltage.

For example, between time t2 and time t6, a large surge current exceeding a steady state flows through the transistor 100a. For example, the surge current is maximized at time t4.

Between time t2 and time t3, similarly to the first embodiment, a positive gate voltage Vg is applied to the gate electrode 18. Between time t2 and time t3, a positive voltage is applied to the gate electrode 18. The gate voltage Vg is, for example, +15 V. Between time t2 and time t3, the gate voltage Vg to be applied to the gate electrode 18 is an example of the first positive voltage.

At time t3, the voltage of the source electrode 12 of the transistor 100a exceeds the first threshold voltage. The first threshold voltage is a predetermined voltage value. The first threshold voltage is an example of the first threshold. The voltage of the source electrode 12 is measured by the voltmeter 100f.

At time t3, the comparison circuit 100c determines that the current flowing from the source electrode 12 to the drain electrode 14 of the transistor 100a exceeds the first threshold voltage. The comparison circuit 100c makes a determination by comparing the measurement value measured by the voltmeter 100f with the first threshold voltage.

At time t3, a negative gate voltage Vg lower than the threshold voltage of the transistor 100a is applied to the gate electrode 18. At time t3, a negative voltage is applied to the gate electrode 18. The gate voltage Vg is, for example, −15 V. At time t3, the gate voltage Vg to be applied to the gate electrode 18 is an example of the first negative voltage.

As a result of the comparison in the comparison circuit 100c, when the measurement value of the voltage of the source electrode 12 exceeds the first threshold voltage, the first negative voltage is applied to the gate electrode 18 by the gate driver circuit 100d.

Between time t3 and time t5, a negative gate voltage Vg is applied to the gate electrode 18, similarly to the first embodiment. Between time t3 and time t5, a negative voltage is applied to the gate electrode 18. The gate voltage Vg is, for example, −15 V. Between time t3 and time t5, the gate voltage Vg to be applied to the gate electrode 18 is an example of the first negative voltage.

At time t5, the voltage of the source electrode 12 of the transistor 100a falls below the second threshold voltage. The second threshold voltage is an example of the second threshold. The second threshold voltage may be equal to the first threshold voltage, for example. The second threshold voltage is lower than the first threshold voltage, for example.

At time t5, the comparison circuit 100c determines that the voltage of the source electrode 12 of the transistor 100a falls below the second threshold voltage. The comparison circuit 100c makes a determination by comparing the measurement value measured by the voltmeter 100f with the second threshold voltage.

At time t5, a positive gate voltage Vg higher than the threshold voltage of the transistor 100a is applied to the gate electrode 18. At time t5, a positive voltage is applied to the gate electrode 18. The gate voltage Vg is, for example, +15 V. At time t5, the gate voltage Vg to be applied to the gate electrode 18 is an example of a second positive voltage.

As a result of the comparison in the comparison circuit 100c, when the measurement value of the voltage of the source electrode 12 falls below the second threshold voltage, the second positive voltage is applied to the gate electrode 18 by the gate driver circuit 100d.

Between time t5 and time t6, similarly to the first embodiment, a positive gate voltage Vg is applied to the gate electrode 18. Between time t5 and time t6, a positive voltage is applied to the gate electrode 18. The gate voltage Vg is, for example, +15 V. Between time t5 and time t6, the gate voltage Vg to be applied to the gate electrode 18 is an example of the second positive voltage.

Between time t6 and time t7, similarly to the first embodiment, a positive gate voltage Vg is applied to the gate electrode 18. Between time t6 and time t7, a positive voltage is applied to the gate electrode 18. The gate voltage Vg is, for example, +15 V. Between time t6 and time t7, the gate voltage Vg to be applied to the gate electrode 18 is an example of the second positive voltage.

According to the semiconductor module 101 of the modification of the first embodiment, similarly to the semiconductor module 100 of the first embodiment, when the surge current flows through the transistor 100a included in the semiconductor module 101, the negative voltage is applied to the gate electrode 18. Therefore, the surge current resistance can be improved.

In the semiconductor module 101 according to the modification of the first embodiment, the second threshold voltage is preferably lower than the first threshold voltage as illustrated in FIG. 15 to improve the surge current resistance.

As illustrated in FIG. 15, for example, the voltage of the source electrode 12 of the transistor 100a shows a behavior of showing a peak at a stage when the surge current starts flowing and then decreasing. Therefore, when the second threshold voltage and the first threshold voltage are equalized, the current flowing through the transistor 100a at time t5 may become larger than the current flowing through the transistor 100a at time t3. In this case, when a positive voltage is applied to the gate electrode 18 at time t5, the current flowing through the transistor 100a may exceed the maximum allowable peak current value.

By setting the second threshold voltage lower than the first threshold voltage, the current flowing through the transistor 100a at time t5 can be made equal to or less than the current flowing through the transistor 100a at time t3. Therefore, by applying a positive voltage to the gate electrode 18 at time t5, there is no possibility of exceeding the maximum allowable peak current value, and the surge current resistance of the semiconductor module 101 is improved.

As described above, according to the first embodiment and the modification, a semiconductor device with an improved surge current resistance is realized. Further, according to the first embodiment and the modification, a semiconductor device in which power loss is reduced is realized.

### Second Embodiment

A semiconductor device and a method of controlling the semiconductor device according to a second embodiment are different from the semiconductor device and the method of controlling the semiconductor device according to the first embodiment in that a first electrode contacts a first semiconductor region. That is, the semiconductor device according to the second embodiment is different from the semiconductor device according to the first embodiment in that a transistor includes a Schottky diode as a built-in diode. Hereinafter, description of contents overlapping with those of the first embodiment may be partially omitted.

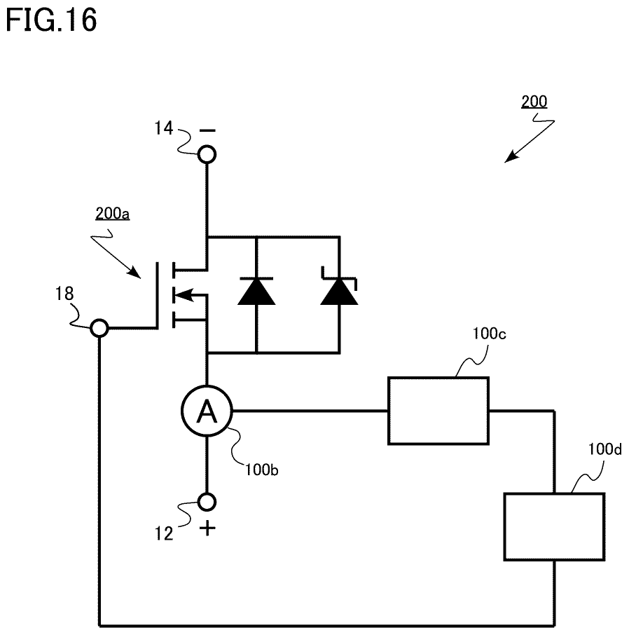

FIG. 16 is a block diagram of the semiconductor device according to the second embodiment. The semiconductor device according to the second embodiment is a semiconductor module 200 including a transistor 200a using silicon carbide.

The semiconductor module 200 includes the transistor 200a, an ammeter 100b, a comparison circuit 100c, and a gate driver circuit 100d.

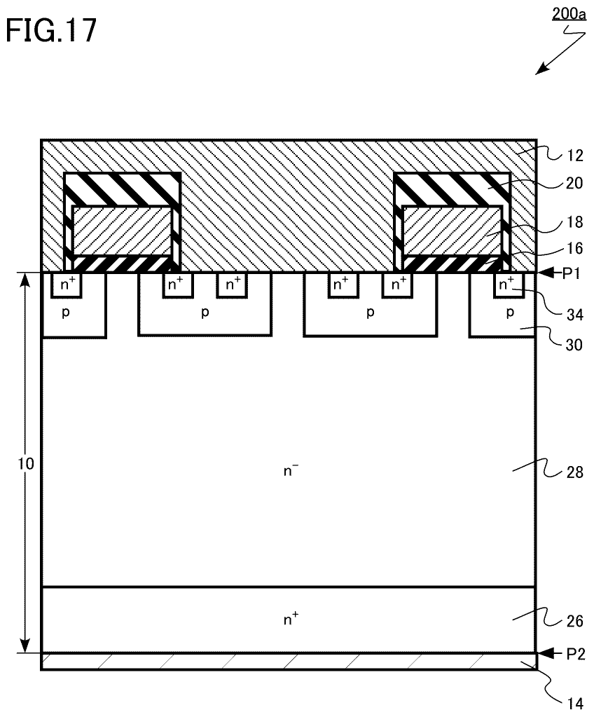

FIG. 17 is a schematic cross-sectional view of the transistor according to the second embodiment. FIG. 17 is a cross-sectional view of the transistor 200a.

The transistor 200a is a planar gate type vertical MOSFET using silicon carbide. The transistor 200a is, for example, a double implantation MOSFET (DIMOSFET) in which a body region and a source region are formed by ion implantation. The transistor 200a is a vertical n-channel MOSFET using electrons as carriers.

The transistor 200a includes a silicon carbide layer 10, a source electrode 12 (first electrode), a drain electrode 14 (second electrode), a gate insulating layer 16, a gate electrode 18, and an interlayer insulating layer 20.

In the silicon carbide layer 10, an n⁺-type drain region 26, an n⁻-type drift region 28 (first semiconductor region), a p-type body region 30 (second semiconductor region), and an n⁺-type source region 34 (third semiconductor region) are provided.

The source electrode 12 is provided on the side of a first plane P1 of the silicon carbide layer 10. The source electrode 12 contacts the first plane P1.

The source electrode 12 contacts the drift region 28, the body region 30, and the source region 34. The source electrode 12 contacts the drift region 28 on the first plane P1.

The source electrode 12 includes a metal. The metal forming the source electrode 12 has a stacked structure of titanium (Ti) and aluminum (Al), for example.

A portion of the source electrode 12 contacting the body region 30 and the source region 34 is, for example, metal silicide. The metal silicide is, for example, titanium silicide or nickel silicide.

The contact between the body region 30 and the source electrode 12 and the contact between the source region 34 and the source electrode 12 are, for example, ohmic contact.

The contact between the drift region 28 and the source electrode 12 is, for example, Schottky contact.

As illustrated in FIG. 16, in the transistor 200a, a pn junction diode and a Schottky junction diode are connected as built-in diodes between the source electrode 12 and the drain electrode 14.

For example, a case where the transistor 200a is used as a switching element connected to an inductive load will be considered. When the transistor 200a is turned off, a voltage at which the source electrode 12 is positive with respect to the drain electrode 14 may be applied due to a load current caused by the inductive load. In this case, a forward current flows through the built-in diode. This state is also referred to as a reverse conduction state.

When a voltage between the source electrode 12 and the drain electrode 14 exceeds a forward voltage (Vf) of the Schottky junction diode, a forward current flows through the Schottky junction diode. When the voltage between the source electrode 12 and the drain electrode 14 exceeds the forward voltage (Vf) of the pn junction diode, the forward current flows through the pn junction diode. The forward voltage (Vf) of the Schottky junction diode is lower than the forward voltage (Vf) of the pn junction diode.

According to the semiconductor module 200 of the second embodiment, similarly to the semiconductor module 100 of the first embodiment, when a surge current flows through the transistor 200a included in the semiconductor module 200, a negative voltage is applied to the gate electrode 18, so that a surge current resistance can be improved.

In addition, the transistor 200a includes, as a built-in diode, a Schottky junction diode having a forward voltage (Vf) lower than the forward voltage (Vf) of the pn junction diode. Therefore, for example, when the voltage between the source electrode 12 and the drain electrode 14 becomes higher than the forward voltage (Vf) of the Schottky junction diode built in the transistor 200a between time t0 and time t1 in FIG. 4, a current can flow through the Schottky junction diode. Therefore, the semiconductor module 200 of the second embodiment can start flowing a reflux current faster than the semiconductor module 100 of the first embodiment, and the power loss can be further reduced.

### Modification

A semiconductor device according to a modification of the second embodiment is different from the semiconductor device according to the second embodiment in including a detector that detects a voltage of a first electrode in a state where the voltage of the first electrode is a positive voltage higher than the voltage of the second electrode. The semiconductor device according to the modification of the second embodiment is different from the semiconductor device according to the modification of the first embodiment in that a transistor includes a Schottky junction diode as a built-in diode.

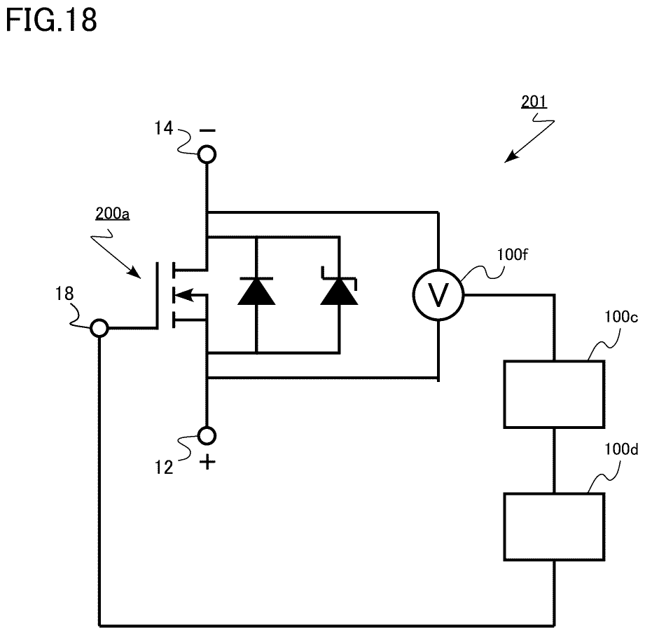

FIG. 18 is a block diagram of the semiconductor device according to the modification of the second embodiment. The semiconductor device according to the modification of the second embodiment is a semiconductor module 201 including a transistor 200a using silicon carbide.

The semiconductor module 201 includes the transistor 200a, a voltmeter 100f, a comparison circuit 100c, and a gate driver circuit 100d.

According to the semiconductor module 201 of the modification of the second embodiment, similarly to the semiconductor module 200 of the second embodiment, when a surge current flows through the transistor 200a included in the semiconductor module 201, a negative voltage is applied to the gate electrode 18, so that a surge current resistance can be improved.

As described above, according to the second embodiment and the modification, a semiconductor device with an improved surge current resistance is realized. Further, according to the second embodiment and the modification, a semiconductor device in which power loss is further reduced is realized.

In the first and second embodiments, the case where the semiconductor region is silicon carbide (SiC) has been described as an example, but the semiconductor region may be, for example, silicon (Si) or a nitride semiconductor.

In the first and second embodiments, the case where 4H-SiC is used as a crystal structure of SiC has been described as an example. However, the present disclosure can also be applied to a device using SiC of other crystal structure such as 6H-SiC and 3C-SiC. Further, it is also possible to apply a face other than a (0001) face to a surface of the silicon carbide layer 10.

In the first and second embodiments, although aluminum (Al) has been exemplified as the p-type impurity, boron (B) can also be used. In addition, although nitrogen (N) and phosphorus (P) have been exemplified as the n-type impurity, arsenic (As), antimony (Sb), and the like can also be applied.

While certain embodiments have been described, these embodiments have been presented by way of example only, and are not intended to limit the scope of the inventions. Indeed, the semiconductor device and the method of controlling the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a transistor, the transistor including a first electrode, a second electrode, an n-type first semiconductor region provided between the first electrode and the second electrode and electrically connected to the second electrode, a p-type second semiconductor region provided between the first semiconductor region and the first electrode and electrically connected to the first electrode, an n-type third semiconductor region provided between the second semiconductor region and the first electrode and electrically connected to the first electrode, and a gate electrode facing the second semiconductor region;
a detector configured to detect a voltage of the first electrode or a current flowing from the first electrode to the second electrode in a state where the voltage of the first electrode is a positive voltage higher than a voltage of the second electrode;
a comparison circuit configured to compare a measurement value measured by the detector with a first threshold in the state; and
a gate driver circuit configured to apply a first positive voltage higher than a threshold voltage of the transistor to the gate electrode in the state, and apply a first negative voltage to the gate electrode when the measurement value exceeds the first threshold as a result of comparison in the comparison circuit.

2. The semiconductor device according to claim 1, wherein the first electrode contacts the first semiconductor region.

3. The semiconductor device according to claim 2, wherein the contact between the first electrode and the first semiconductor region is Schottky contact.

4. The semiconductor device according to claim 1, wherein when the first negative voltage is applied to the gate electrode, the second semiconductor region facing the gate electrode is in an accumulation state.

5. The semiconductor device according to claim 1, wherein
after applying the first negative voltage to the gate electrode, in the state, the comparison circuit compares the measurement value measured by the detector with a second threshold, and
in the state, when the measurement value falls below the second threshold in the comparison circuit, the gate driver circuit applies a second positive voltage higher than the threshold voltage to the gate electrode.

6. The semiconductor device according to claim 5, wherein when the detector detects the voltage of the first electrode, the second threshold is a voltage lower than the first threshold.

7. The semiconductor device according to claim 1, wherein the first semiconductor region, the second semiconductor region, and the third semiconductor region are silicon carbide.

8. The semiconductor device according to claim 1, wherein when the detector detects a current flowing from the first electrode to the second electrode, the first threshold is a current value, and the first threshold is 0.6 times or more and 1.0 times or less a maximum allowable peak current value (I_{FSM}) of the transistor under an operation condition that +15 V is continuously applied to the gate electrode.

9. The semiconductor device according to claim 1, wherein when the detector detects a current flowing from the first electrode to the second electrode, the first threshold is a current value, and the first threshold is 0.8 times or more and 1.0 times or less a maximum allowable peak current value (I_{FSM}) of the transistor under an operation condition that +15 V is continuously applied to the gate electrode.

10. The semiconductor device according to claim 1, wherein when the detector detects a current flowing from the first electrode to the second electrode, a delay time from when the measurement value exceeds the first threshold to when the first negative voltage is applied to the gate electrode is less than 2 ms.

11. The semiconductor device according to claim 1, wherein when the detector detects a current flowing from the first electrode to the second electrode, a delay time from when the measurement value exceeds the first threshold to when the first negative voltage is applied to the gate electrode is less than 200 μs.

12. A method of controlling a semiconductor device including a transistor, the transistor including a first electrode, a second electrode, an n-type first semiconductor region provided between the first electrode and the second electrode and electrically connected to the second electrode, a p-type second semiconductor region provided between the first semiconductor region and the first electrode and electrically connected to the first electrode, an n-type third semiconductor region provided between the second semiconductor region and the first electrode and electrically connected to the first electrode, and a gate electrode facing the second semiconductor region, the method comprising:
applying a positive voltage higher than a voltage of the second electrode to the first electrode;
applying a first positive voltage higher than a threshold voltage of the transistor to the gate electrode;
detecting a voltage of the first electrode or a current flowing from the first electrode to the second electrode; and
comparing a detected measurement value with a first threshold, and applying a first negative voltage to the gate electrode when the measurement value exceeds the first threshold.

13. The method of controlling the semiconductor device according to claim 12, wherein the first electrode contacts the first semiconductor region.

14. The method of controlling the semiconductor device according to claim 13, wherein the contact between the first electrode and the first semiconductor region is Schottky contact.

15. The method of controlling the semiconductor device according to claim 12, wherein when the first negative voltage is applied to the gate electrode, the second semiconductor region facing the gate electrode is in an accumulation state.

16. The method of controlling the semiconductor device according to claim 12, wherein
after the applying the first negative voltage to the gate electrode, the measurement value is compared with a second threshold, and
when the measurement value exceeds the second threshold, a second positive voltage higher than the threshold voltage is applied to the gate electrode.

17. The method of controlling the semiconductor device according to claim 16, wherein when the voltage of the first electrode is detected in the detecting, the second threshold is a voltage lower than the first threshold.

18. The method of controlling the semiconductor device according to claim 12, wherein the first semiconductor region, the second semiconductor region, and the third semiconductor region are silicon carbide.

19. The method of controlling the semiconductor device according to claim 12, wherein when the current flowing from the first electrode to the second electrode is detected in the detecting, the first threshold is a current value, and the first threshold is 0.6 times or more and 1.0 times or less a maximum allowable peak current value (I_{FSM}) of the transistor under an operation condition that +15 V is continuously applied to the gate electrode.

20. The method of controlling the semiconductor device according to claim 12, wherein when the current flowing from the first electrode to the second electrode is detected in the detecting, the first threshold is a current value, and the first threshold is 0.8 times or more and 1.0 times or less a maximum allowable peak current value (I_{FSM}) of the transistor under an operation condition that +15 V is continuously applied to the gate electrode.

21. The method of controlling the semiconductor device according to claim 12, wherein when the current flowing from the first electrode to the second electrode is detected in the detecting, a delay time from when the measurement value exceeds the first threshold to when the first negative voltage is applied to the gate electrode is less than 2 ms.

22. The method of controlling the semiconductor device according to claim 12, wherein when the current flowing from the first electrode to the second electrode is detected in the detecting, a delay time from when the measurement value exceeds the first threshold to when the first negative voltage is applied to the gate electrode is less than 200 μs.
